(19) United States
(12) Patent Application Publication
(10) Pub. No.: US 2006/0286728 A1
(43) Pub. Date: Dec. 21, 2006

(54) Method for forming recess gate of semiconductor device

(75) Inventor: Wan Soo Kim, Chungcheongbuk-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/321,595

(22) Filed: Dec. 30, 2005

(30) Foreign Application Priority Data
Jun. 16, 2005 (KR) 10-2005-0052091

(51) Int. Cl. H01L 21/338

(52) U.S. Cl. 438/180

(57) ABSTRACT

A method for forming a recess gate of a semiconductor device secures a sufficient overlap margin between a recess gate region and a gate electrode to prevent a phenomenon resulting from mis-alignment when a recess gate electrode is formed, thereby improving process defects and minimizing Vt movement between cells.

### BACKGROUND OF THE INVENTION

1. Field of the Invention

The present invention generally relates to a method for forming a recess gate of a semiconductor device, and more specifically, to a technology of securing a sufficient overlap margin between a recess gate region and a gate electrode to improve process defects and minimize a variation of Cell Vt between recess gates.

2. Description of the Related Art

A recess gate region refers to a portion where a semiconductor substrate is etched and a channel region is extended, and a gate refers to a gate electrode layer and a spacer that are overlapped with the recess gate region and formed on the semiconductor substrate. A recess gate refers to the combination thereof.

FIGS. 1 through 5 are cross-sectional views illustrating a conventional method for forming a recess gate of a semiconductor device.

Referring to FIG. 1, a device isolation film 20 is formed on a semiconductor substrate 10. Then, a hard mask pattern 30 and a first photoresist pattern 40 that define a recess gate region are formed on the semiconductor substrate 10.

Referring to FIG. 2, the exposed semiconductor substrate 10 is etched at a predetermined thickness with a first photoresist pattern 40 and a hard mask pattern 30 to form a recess gate region. Then, the first photoresist pattern 40 and the hard mask pattern 30 are removed. Thereafter, a gate oxide film 50 is formed on the entire surface of the semiconductor substrate 10 including the recess gate region.

Preferably, the recess gate region is formed at a thickness ranging from 1000 Åto 1400 Å.

Referring to FIG. 3, a polysilicon layer 60 for filling the recess gate region is formed. Then, the polysilicon layer 60 is planarized, and a deposition structure including a gate metal layer 70 and a hard mask layer 80 is formed thereon. Thereafter, a second photoresist pattern 90 that defines a recess gate is formed.

Referring to FIG. 4, the deposition structure is etched with a second photoresist pattern 90 to form a recess gate electrode pattern. Then, the second photoresist pattern 90 is removed. Next, a spacer 95 is formed on a sidewall of the recess gate electrode pattern to form a recess gate.

However, mis-alignment occurs between the second photoresist pattern and the recess gate region when the recess gate is formed, so that the recess gate as shown ‘A’ of FIG. 5 does not cover the overall recess gate region.

In the above conventional method for forming a recess gate of a semiconductor device, since the formed recess gate does not cover the recess gate region completely, process defects resulting from short between a landing plug contact and a gate electrode are generated and cell Vt is changed.

### SUMMARY OF THE INVENTION

Various embodiments are directed at providing a method for forming a recess gate of a semiconductor device so as to improve process defects and minimize movement of cell Vt. In the method, first and second recess gate regions are formed through a 2-step etching process when a recess gate region is formed. First, the first recess gate region is formed, and then an oxidizing process for prevent increase of the line-width of the first recess gate region is performed to secure a sufficient overlap margin between a recess gate and a recess gate region. The recess gate region is extended since a thick oxide film is formed in the second recess gate region. As a result, a desired line-width of the target to the first recess gate region can be obtained.

According to one embodiment of the present invention, a method for forming a recess gate of a semiconductor device comprises the steps of: forming a first recess gate region on a semiconductor substrate having a device isolation film; forming a spacer on a sidewall of the first recess gate region; etching the first recess gate region at a predetermined depth with the spacer as an etching mask to form a second recess gate region; oxidizing the second recess gate region and the spacer to form an oxide film; removing the oxide film, and the performing an oxidizing process on the entire surface of the semiconductor substrate to form a gate oxide film; and forming a gate on a gate region including the second recess gate region.

More specifically, a method for forming a recess gate of a semiconductor device comprises the steps of: forming a stacked structure of a pad oxide film pattern and a hard mask layer pattern on a semiconductor substrate having a device isolation film, the stacked structure defining a first recess gate region; etching the semiconductor substrate by a predetermined thickness using the hard mask layer pattern as an etching mask to form the first recess gate region; forming a first spacer on a sidewall of the first recess gate region and the hard mask layer pattern; etching the semiconductor substrate by a predetermined thickness using the first spacer as an etching mask to form a second recess gate region; oxidizing the second recess gate region and the first spacer to form a sacrifice oxide film; removing the sacrifice oxide film, and the performing a first oxidizing process to form a first gate oxide film; removing the hard mask layer pattern and the first gate oxide film, and the performing a second oxidizing process on the entire surface to form a second gate oxide film; forming a polysilicon layer, a gate metal layer and a gate hard mask layer on the entire surface of the semiconductor substrate including the second recess gate region to form a gate by an etching process using a gate mask pattern as an etching mask; and forming a second spacer on a sidewall of the gate.

### BRIEF DESCRIPTION OF THE DRAWINGS

Other aspects and advantages of the present invention will become apparent upon reading the following detailed description and upon reference to the drawings in which:

FIGS. 1 through 5 are cross-sectional views illustrating a conventional method for forming a recess gate of a semiconductor device; and

FIGS. 6 through 13 are cross-sectional views illustrating a method for forming a recess gate of a semiconductor device according to an embodiment of the present invention.

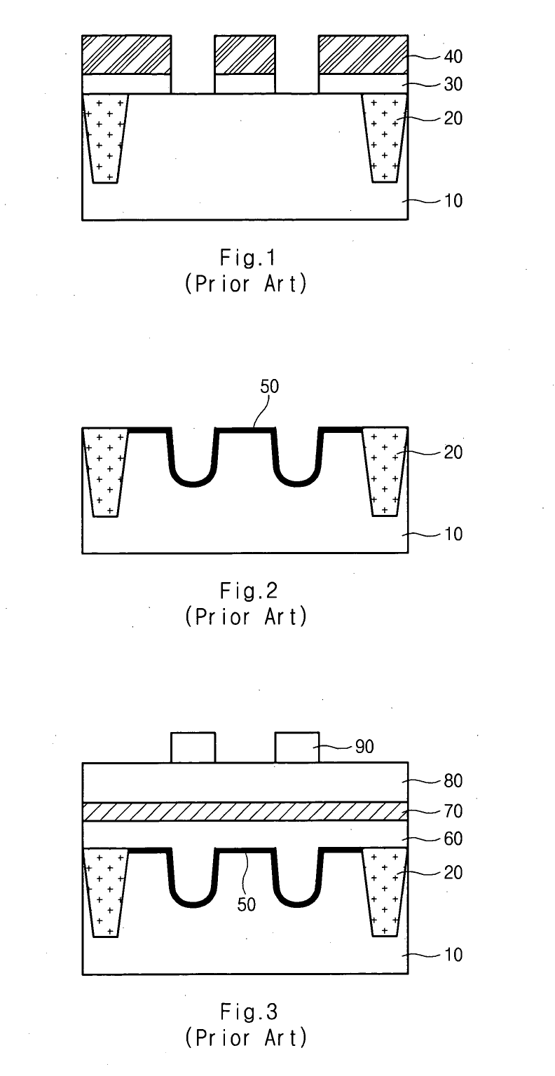

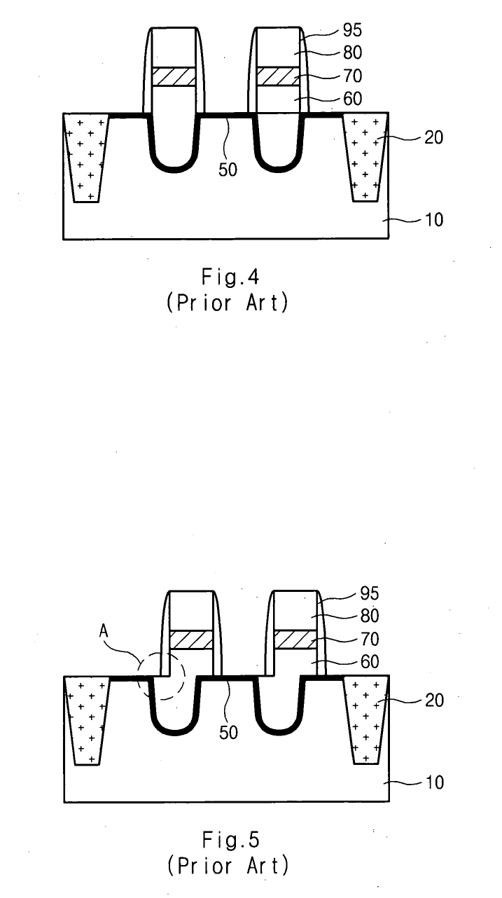

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like parts.

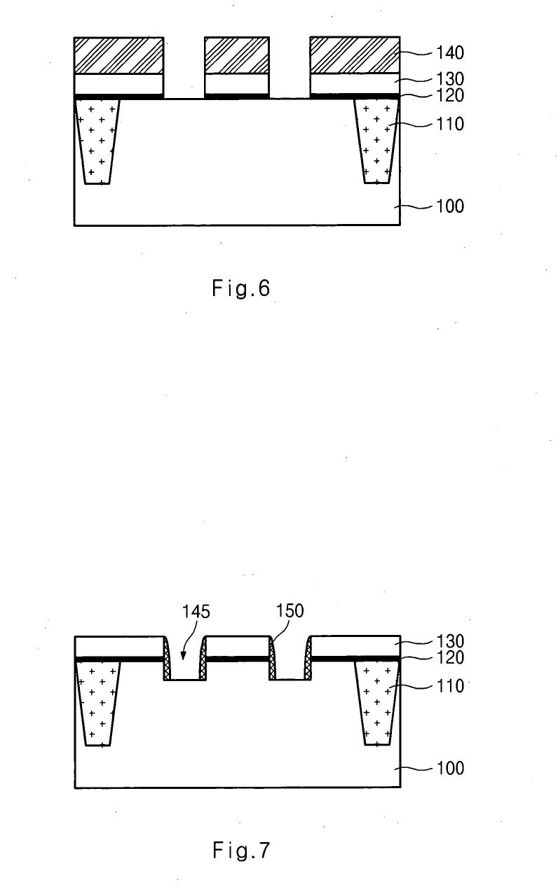

FIGS. 6 through 13 are cross-sectional views illustrating a method for forming a recess gate of a semiconductor device according to an embodiment of the present invention.

Referring to FIG. 6, a device isolation film 110 is formed on a semiconductor substrate 100. Then, a pad oxide film and a hard mask layer(?) are formed on the semiconductor substrate 100. A photoresist pattern 140 that defines a recess gate region is formed on the hard mask. Thereafter, the hard mask and the pad oxide film are etched with the photoresist pattern 140 as an etching mask to form a pad oxide film pattern 120 and a hard mask pattern 130 that define a recess gate region. Next, the photoresist pattern 140 is removed. Preferably, the hard mask pattern 130 is a nitride film or a polysilicon film.

Referring to FIG. 7, the exposed semiconductor substrate 100 is etched at a predetermined thickness using the hard mask pattern 130 as an etching mask to form a first recess gate region 145. Then, a first spacer 150 is formed on a sidewall of the hard mask pattern 130 and the first recess gate region 145. The first recess gate region 145 is preferably formed at a thickness ranging from 400 Å to 600 Å. More preferably, the first spacer 150 is a polysilicon layer it should be understood that all gates in FIG. 7 have a similar construction.

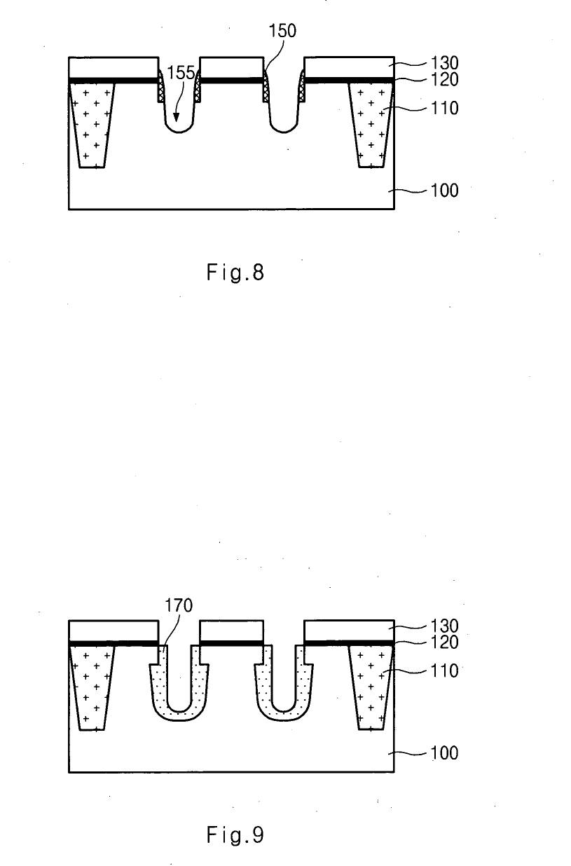

Referring to FIG. 8, the lower portion of the first recess gate region 145 is etched at a predetermined thickness with the first spacer 150 of FIG. 7 as a mask to form a second recess gate region 155.

Preferably, the second recess gate region 155 is formed at a thickness ranging from 300 Å to 500 Å in the first recess gate region 145 of FIG. 7.

Referring to FIG. 9, the surface of the second recess gate region 155 and the first spacer 150 are oxidized at the same time to form a sacrifice oxide film 170.

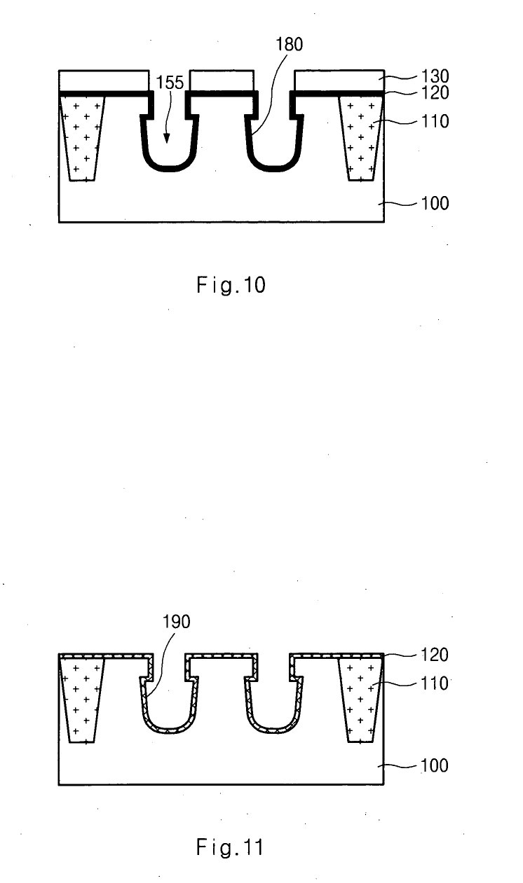

Referring to FIG. 10, the sacrifice oxide film 170 is removed using a wet etching method including BOE or HF solution. Then, a first oxidizing process is performed to form a first gate oxide film 180 in the first recess gate region 145 and the second recess gate region 155. Thereafter, the hard mask pattern 130 is removed. Preferably, the hard mask pattern 130 is removed using phosphate of 100 to 200° C.

Referring to FIG. 11, a second oxidizing process is performed on the entire surface of the semiconductor substrate 100 to form a second gate oxide film 190.

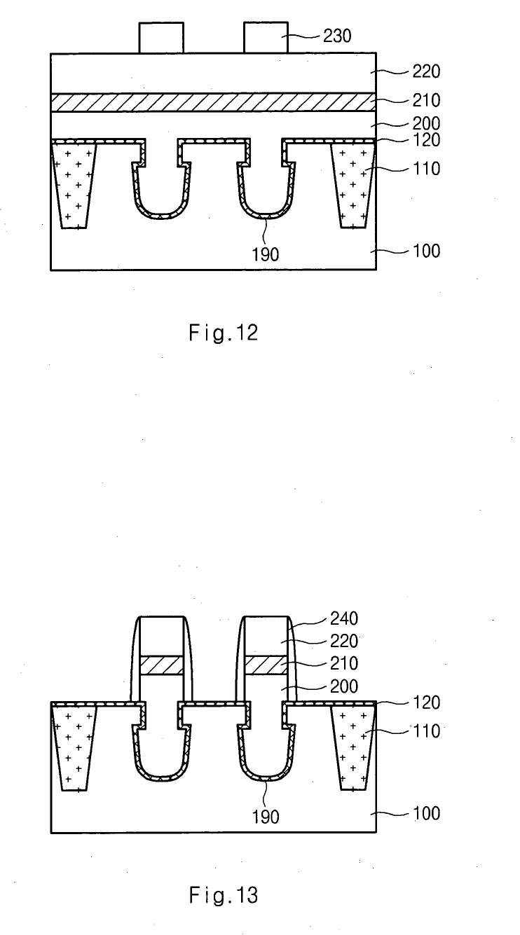

Referring to FIG. 12, a stacked structure including a polysilicon layer 120, a gate metal layer 210 and a gate hard mask layer 220 is formed on the entire surface of the semiconductor substrate including the second recess gate region 155. A second photoresist pattern 230 that defines a gate is formed on the deposition structure.

Preferably, the gate metal layer 210 is selected from tungsten, aluminum and tungsten silicide. The gate hard mask layer 220 is preferably a nitride film.

Referring to FIG. 13, the stacked structure is etched using the second photoresist pattern 230 as an etching mask, and a second spacer 240 is formed on the gate sidewall to form a recess gate.

Preferably, a width of the first recess gate region 145 is equal to or smaller than that of the gate and it is smaller than that of the second recess gate region 150.

As described above, in a method for forming a recess gate of a semiconductor device according to one embodiment of the present invention, a sufficient overlap margin between a recess gate region and a gate electrode is secured to prevent a phenomenon resulting from mis-alignment when a recess gate electrode is formed, thereby improving process defects and minimizing a variation of Cell Vt between cells.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A method for forming a recess gate of a semiconductor device, comprising the steps of:
forming a first recess gate region on a semiconductor substrate having a device isolation film;
forming a spacer on a sidewall of the first recess gate region;
etching the first recess gate region at a predetermined depth using the spacer as an etching mask to form a second recess gate region;
oxidizing the surface of the second recess gate region and the spacer to form a sacrifice oxide film;
removing the sacrifice oxide film, and then performing an oxidizing process on a surface of the resultant semiconductor device to form a gate oxide film; and
forming a gate on a gate region including the second recess gate region.

2. The method according to claim 1, wherein the first recess gate region is formed at a thickness ranging from about 400 Å to about 600 Å.

3. The method according to claim 1, wherein the second recess gate region is formed at a thickness ranging from about 300 Å to about 500 Å.

4. The method according to claim 1, wherein a width of the first recess gate region is equal to or smaller than a width of the gate and it is smaller than a width of the second recess gate region.

5. The method according to claim 1, wherein the sacrifice oxide film is removed using a wet etching method.

6. The method according to claim 5, wherein the wet etching method includes BOE or HF solution.

7. A method for forming a recess gate of a semiconductor device, comprising the steps of:
forming a stacked structure of a pad oxide film pattern and a hard mask layer pattern on a semiconductor substrate having a device isolation film, the stacked structure defining a first recess gate region;
etching the semiconductor substrate by a predetermined thickness using the hard mask layer pattern as an etching mask to form the first recess gate region;
forming a first spacer on a sidewall of the first recess gate region and the hard mask layer pattern;
etching the first recess gate region by a predetermined thickness using the first spacer as an etching mask to form a second recess gate region;
oxidizing the second recess gate region and the first spacer to form a sacrifice oxide film;
removing the scarifice oxide film, and then performing a first oxidizing process to form a first gate oxide film;
removing the hard mask layer pattern and the first gate oxide film, and then performing a second oxidizing process on the entire surface to form a second gate oxide film;
forming a polysilicon layer, a gate metal layer and a gate hard mask layer on the entire surface of the semiconductor substrate including the second recess gate region to form a gate by an etching process using a gate mask pattern as an etching mask; and
forming a second spacer on a sidewall of the gate.

8. The method according to claim 7, wherein the hard mask layer is a nitride film or a polysilicon film.

9. The method according to claim 7, wherein the first recess gate region is formed at a thickness ranging from about 400 Å to about 600 Å.

10. The method according to claim 7, wherein the second recess gate region is formed at a thickness ranging from about 300 Å to about 500 Å.

11. The method according to claim 7, wherein a width of the first recess gate region is equal to or smaller than a width of the gate and it is smaller than a width of the second recess gate region.

12. The method according to claim 7, wherein the sacrifice oxide film is removed using a wet etching method.

13. The method according to claim 12, wherein the wet etching method includes BOE or HF solution.

14. The method according to claim 7, wherein the hard mask layer pattern is removed using phosphoric acid.
